(19) United States
(12) Patent Application Publication
(10) Pub. No.: US 2026/0082799 A1
(43) Pub. Date: Mar. 19, 2026

(54) DISPLAY PANEL AND DISPLAY DEVICE

(71) Applicant: Wuhan Tianma Microelectronics Co., Ltd. Shanghai Branch, Shanghai (CN)

(72) Inventor: Xi Chen, Shanghai (CN)

(73) Assignee: Wuhan Tianma Microelectronics Co., Ltd. Shanghai Branch, Shanghai (CN)

(21) Appl. No.: 19/400,076

(22) Filed: Nov. 25, 2025

(30) Foreign Application Priority Data
Aug. 21, 2025 (CN) 202511180189.1

(51) Int. Cl. H10K 59/95; H10N 10/17; H10N 10/852; H10N 19/00

(52) U.S. Cl. CPC H10K 59/95; H10N 10/17; H10N 10/852; H10N 19/00

(57) ABSTRACT

Provided are a display panel and a display device. The display panel includes: a base substrate, multiple light-emitting units and multiple thermoelectric conversion units, where the multiple light-emitting units and the multiple thermoelectric conversion units are located on a side of the base substrate in a thickness direction, an orthographic projection of a thermoelectric conversion unit of the multiple thermoelectric conversion units on the base substrate does not overlap with an orthographic projection of a light-emitting unit of the multiple light-emitting units on the base substrate, the thermoelectric conversion unit includes a thermocouple arm, and when a temperature difference exists between two ends of the thermocouple arm facing away from each other, carriers diffuse from a hot end to a cold end to form an electromotive force.

### CROSS-REFERENCE TO RELATED APPLICATION

The present application claims priority to Chinese Patent Application No. 202511180189.1, filed with the China National Intellectual Property Administration (CNIPA) on Aug. 21, 2025, the disclosure of which is incorporated herein by reference in its entirety.

### TECHNICAL FIELD

Embodiments of the present disclosure relate to the field of display technologies and, in particular, to a display panel and a display device.

### BACKGROUND

With the continuous advancements in display technology, display panels have been widely adopted in both industrial applications and daily life. To better satisfy the growing demands, adjustments may be made to the display panels, such as modifying certain internal structures of the display panels, thereby enhancing the power endurance performance of the display panels.

### SUMMARY

The present disclosure provides a display panel and a display device. By additionally providing thermoelectric conversion units in the display panel, the thermoelectric conversion unit is capable of generating an electromotive force in the presence of a temperature difference, and the resulting electrical energy may be supplied to the display panel, thereby increasing the endurance time of the display panel and reducing the power consumption of the display panel.

In a first aspect, embodiments of the present disclosure provide a display panel. The display panel includes a base substrate, multiple light-emitting units and multiple thermoelectric conversion units.

The multiple light-emitting units and the multiple thermoelectric conversion units are located on a side of the base substrate in a thickness direction, and the orthographic projection of the thermoelectric conversion unit on the base substrate does not overlap with the orthographic projection of the light-emitting unit on the base substrate.

The thermoelectric conversion unit includes a thermocouple arm, and when a temperature difference exists between two ends of the thermocouple arm facing away from each other, carriers diffuse from a hot end to a cold end to form an electromotive force.

In a second aspect, the embodiments of the present disclosure further provide a display device. The display device includes the display panel described in the first aspect.

The embodiments of the present disclosure provide a display panel, and multiple light-emitting units and multiple thermoelectric conversion units are provided in the display panel on a side of the base substrate. The multiple light-emitting units are capable of emitting light for display, thereby achieving the display function of the display device. The multiple thermoelectric conversion units are capable of generating an electromotive force in the presence of a temperature difference, and the resulting electrical energy may be supplied to the display panel, thereby increasing the endurance time of the display panel. Specifically, the thermoelectric conversion unit includes a thermocouple arm, and when a temperature difference exists between two ends of the thermocouple arm facing away from each other, carriers diffuse from a hot end to a cold end to form an electromotive force, thereby achieving the generation of electrical energy and reducing the power consumption of the display panel.

### BRIEF DESCRIPTION OF DRAWINGS

FIG. 1 is a structure diagram of a display panel according to an embodiment of the present disclosure;

FIG. 2 is a first enlarged view of region A in FIG. 1;

FIG. 3 is a first sectional view of FIG. 2 taken along a section line B-B′;

FIG. 4 is an enlarged view of a first type of thermoelectric conversion unit according to an embodiment of the present disclosure;

FIG. 5 is a second sectional view of FIG. 2 taken along a section line B-B′;

FIG. 6 is a third sectional view of FIG. 2 taken along a section line B-B′;

FIG. 7 is a first enlarged view of region B in FIG. 1;

FIG. 8 is a sectional view of FIG. 7 taken along a section line C-C′;

FIG. 9 is a second sectional view of FIG. 7 taken along a section line C-C′;

FIG. 10 is a second enlarged view of region A in FIG. 1;

FIG. 11 is a first sectional view of FIG. 10 taken along a section line D-D′;

FIG. 12 is a second enlarged view of region B in FIG. 1;

FIG. 13 is a first sectional view of FIG. 12 taken along a section line E-E′;

FIG. 14 is a second sectional view of FIG. 12 taken along a section line E-E′;

FIG. 15 is a third enlarged view of region B in FIG. 1;

FIG. 16 is a third enlarged view of region B in FIG. 1;

FIG. 17 is an enlarged view of a second type of thermoelectric conversion unit according to an embodiment of the present disclosure;

FIG. 18 is a fourth sectional view of FIG. 2 taken along a section line B-B′; and

FIG. 19 is a structure diagram of a display device according to an embodiment of the present disclosure.

### DETAILED DESCRIPTION

The present disclosure is further described in detail below in conjunction with drawings and embodiments. It is to be understood that the embodiments described herein are intended to illustrate the present disclosure and not to limit the present disclosure. Additionally, it is to be noted that for ease of description, only part, not all, of the structures related to the present disclosure are illustrated in the drawings.

Terms used in the embodiments of the present disclosure are intended only to describe the specific embodiments and not to limit the present disclosure. It is to be noted that the orientation terms such as “on”, “below”, “left”, “right” and the like in embodiments of the present disclosure are described according to the perspective of the drawings and are not to be construed as limiting the present disclosure. In addition, in the context, it is to be understood that when a component is formed “on” or “below” another component, it may be directly formed “on” or “below” another component, and may also be indirectly formed “on” or “below” another component via a middle component. The terms such as “first”, “second” and the like are used only for the purpose of description to distinguish between different components, but are not used for indicating any order, quantity or significance. For those of ordinary skill in the art, specific meanings of the preceding terms in the present disclosure may be understood based on specific situations.

The terms “comprise”, “include” and variations thereof in the present disclosure are intended to be inclusive, that is, “including, but not limited to”. The term “based on” means “at least partially based on”. The term “an embodiment” refers to “at least one embodiment”.

It is to be noted that references to “first”, “second”, and the like in the present disclosure are merely intended to distinguish corresponding content and are not intended to limit an order or an interrelationship.

It is to be noted that the modifications of “a”, “an”, “more than one”, “a plurality of”, “multiple” and the like mentioned in the present disclosure are illustrative rather than restrictive, and that those skilled in the art should understand that unless the context clearly indicates otherwise, these modifications should be understood as “one or more”.

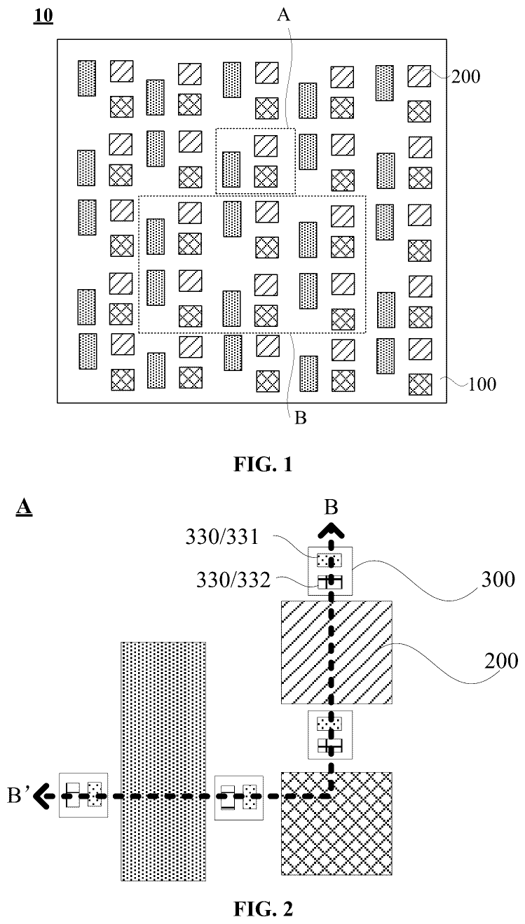

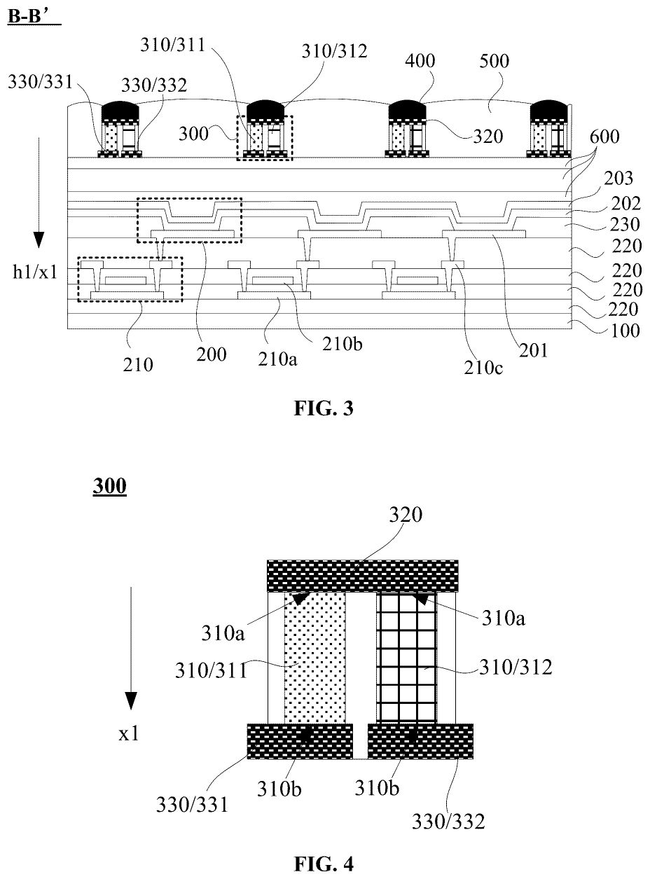

FIG. 1 is a structure diagram of a display panel according to an embodiment of the present disclosure, FIG. 2 is a first enlarged view of region A in FIG. 1, FIG. 3 is a first sectional view of FIG. 2 taken along a section line B-B′, and FIG. 4 is an enlarged view of a first type of thermoelectric conversion unit according to an embodiment of the present disclosure. Referring to FIGS. 1 to 4, embodiments of the present disclosure provide a display panel 10. The display panel 10 includes a base substrate 100, multiple light-emitting units 200 and multiple thermoelectric conversion units 300. The multiple light-emitting units 200 and the multiple thermoelectric conversion units 300 are located on a side of the base substrate 100 in a thickness direction h1, and the orthographic projection of the thermoelectric conversion unit 300 on the base substrate 100 does not overlap with the orthographic projection of the light-emitting unit 200 on the base substrate 100. The thermoelectric conversion unit 300 includes a thermocouple arm 310, and when a temperature difference exists between two ends of the thermocouple arm 310 facing away from each other, carriers diffuse from a hot end to a cold end to form an electromotive force.

Referring to FIG. 1, the display panel 10 includes multiple light-emitting units 200, and the display function of the display panel 10 may be achieved by driving the light-emitting units 200 to emit light. The display panel 10 may include light-emitting units 200 of different colors, including, for example, light-emitting units 200 emitting red light, light-emitting units 200 emitting blue light and light-emitting units 200 emitting green light, thereby achieving the color display performance of the display panel 10.

Specifically, referring to FIG. 3, the display panel 10 further includes a driver circuit 210, and the driver circuit 210 is capable of driving the light-emitting units 200 to emit light for display. The driver circuit 210 includes at least one transistor, and the number of transistors to be provided is not specifically limited in the embodiments of the present disclosure and may be adaptively adjusted according to requirements. Further, the display panel 10 further includes a laminated film structure disposed on a side of the base substrate 100. For example, referring to FIG. 3, the film structure includes an active layer 210a, a gate layer 210b, a source-drain layer 210c, insulating layers 220 disposed between the above-mentioned film layers and the like. The specific film structure may be adaptively adjusted according to different display panels 10 and is not specifically limited in the embodiments of the present disclosure. The display panel 10 may be an organic light-emitting display panel or a liquid crystal display panel, and the specific type of the display panel 10 is not specifically limited in the embodiments of the present disclosure.

FIG. 3 illustrates an example where the display panel 10 is an organic light-emitting display panel. Further, referring to FIG. 3, a light-emitting unit 200 includes a first electrode layer 201, a common light-emitting layer 202 and a second electrode layer 203. In the thickness direction h1 of the base substrate 100, the common light-emitting layer 202 is located between the first electrode layer 201 and the second electrode layer 203, and the first electrode layer 201 is electrically connected to the driver circuit 210, thereby achieving the electrical connection between the driver circuit 210 and the light-emitting unit 200. The luminescence principle of the light-emitting unit 200 may be understood as follows: after a certain voltage is applied to the first electrode layer 201 and the second electrode layer 203, respectively, the holes from the first electrode layer 201 and the electrons from the second electron layer 203 converge in the light-emitting film in the common light-emitting layer 202, and these holes and electrons are further excited to emit light, thereby achieving the light emission of the light-emitting unit 200. The display panel 10 further includes a pixel defining layer 230 for separating the first electrode layers 201 of different light-emitting units 200 from each other, thereby ensuring the light-emitting effect of different light-emitting units 200.

Referring to FIGS. 2 and 3, the display panel 10 further includes multiple thermoelectric conversion units 300. The thermoelectric conversion unit 300 is capable of generating an electromotive force in the presence of a temperature difference in the environment where the thermoelectric conversion unit 300 is located, thereby achieving the generation of electrical energy. Further, the generated electric energy may be supplied to the display panel 10, thereby increasing the endurance time of the display panel 10 and facilitating the reduction of the power consumption of the display panel.

Specifically, referring to FIGS. 2 and 3, the multiple thermoelectric conversion units 300 and the multiple light-emitting units 200 are located on a side of the base substrate 100 in a thickness direction h1, and the orthographic projection of the thermoelectric conversion unit 300 on the base substrate 100 does not overlap with the orthographic projection of the light-emitting unit 200 on the base substrate 100. Therefore, the thermoelectric conversion units 300 provided in the display panel 10 do not interfere with the light emitted from the light-emitting units 200, thereby avoiding affecting the display effect of the display panel 10.

Specifically, referring to FIGS. 3 and 4, the thermoelectric conversion unit 300 includes a thermocouple arm 310, and when a temperature difference exists between two ends of the thermocouple arm 310 facing away from each other, carriers diffuse from a hot end to a cold end to form an electromotive force. Referring to FIG. 3, the thermocouple arm 310 includes a hot end (illustrated as 310a in FIG. 4) and a cold end (illustrated as 310b in FIG. 4), and when there is a temperature difference, the carriers may diffuse from the hot end 310a to the cold end 310b to form an electromotive force, thereby forming a current and achieving the generation of electric energy. A connection wire (not specifically shown in the figure) is provided in the display panel 10, and the connection wire may transmit the electric energy generated by the thermoelectric conversion unit 300 to a power module (not specifically shown in the figure) of the display panel 10, thereby achieving the storage of the electric energy.

The thermoelectric efficiency of the thermoelectric conversion unit 300 satisfies the following formulas:

$$η = \frac{P}{Q} = \frac{Th - Tc}{Th} * \frac{\sqrt{1 + Z \times Tm} - 1}{\sqrt{1 + Z \times Tm} + \frac{Tc}{Th}} \qquad ( 1 )$$

$$Tm = \frac{Th + Tc}{2} \qquad ( 2 )$$

$$Z \times T = \frac{{s}^{2} σ}{k} * T . \qquad ( 3 )$$

In Formula (1), η denotes a total efficiency converted into electric energy by the thermoelectric conversion unit 300, P denotes an output electric power of the thermoelectric conversion unit 300, Q denotes a heat flow input from the hot end, Th denotes a temperature of the hot end, and Tc denotes a temperature of the cold end. Tm denotes an average temperature of the hot end and the cold end of the thermocouple arm 310. In Formula (3), s denotes a Seebeck coefficient, σ denotes an electrical conductivity, and k denotes a thermal conductivity.

Specifically, the value of Tm may be calculated according to Formula (2), and the value of Z×Tm may be derived by substituting the obtained Tm into T in Formula (3). Z×Tm may be understood as the material's figure of merit. By substituting Z×Tm into Formula (1), the total efficiency η of the thermoelectric conversion unit 300 may be calculated. For example, when Z×Tm is 1, the temperature Th of the hot end is 50° C. (323.1 K) and the temperature Tc of the cold end is 45° C. (318.1 K), by substituting these values into the formulas, the total efficiency η converted into electric energy by the thermoelectric conversion unit 300 is approximately 0.26%.

Therefore, the thermoelectric conversion unit 300 may achieve the conversion of the temperature difference into electrical energy and supply the electrical energy to the display panel 10, thereby increasing the endurance time of the display panel 10 and facilitating the improvement of the overall working efficiency of the display panel 10. In other words, the thermoelectric conversion unit 300 in the display panel 10 may generate electrical energy based on the temperature difference between the environment in which the display panel 10 is located and the interior of the display panel 10, thereby increasing the endurance time of the display panel 10. Further, if the display panel 10 is in an extreme environment, the display panel 10 may be charged by the thermoelectric conversion unit 300, thereby improving the overall working efficiency of the display panel 10.

In summary, the embodiments of the present disclosure provide a display panel, and multiple light-emitting units and multiple thermoelectric conversion units are provided in the display panel on a side of the base substrate. The multiple light-emitting units are used to achieve the display function of the display device. The multiple thermoelectric conversion units may generate an electromotive force in the presence of a temperature difference, and the resulting electrical energy may be supplied to the display panel, thereby increasing the endurance time of the display panel and reducing the power consumption of the display panel.

Referring to FIGS. 1 to 4, the thermocouple arm 310 includes a first thermocouple arm 311 and a second thermocouple arm 312. The first thermocouple arm 311 is made of a P-type semiconductor material, and the second thermocouple arm 312 is made of an N-type semiconductor material. The first thermocouple arm 311 and the second thermocouple arm 312 extend in parallel in a first direction X1 and are insulated from each other, where the first direction X1 and the base substrate 100 intersect. The thermoelectric conversion unit 300 further includes a hot-end electrode 320 and a cold-end electrode 330. The cold-end electrode 330 includes a first cold-end sub-electrode 331 and a second cold-end sub-electrode 332. The hot-end electrode 320 is located on a side of the first thermocouple arm 311 and the second thermocouple arm 312 facing away from the base substrate 100, and the hot-end electrode 320 is electrically connected to the first thermocouple arm 311 and the second thermocouple arm 312, respectively. The cold-end electrode 330 is located on a side of the first thermocouple arm 311 and the second thermocouple arm 312 facing the base substrate 100, the first cold-end sub-electrode 331 is electrically connected to the first thermocouple arm 311, the second cold-end sub-electrode 332 is electrically connected to the second thermocouple arm 312, and the first cold-end sub-electrode 331 is insulated from the second cold-end sub-electrode 332.

Specifically, referring to FIGS. 3 and 4, the thermocouple arm 310 includes a first thermocouple arm 311 and a second thermocouple arm 312. Both of the first thermocouple arm 311 and the second thermocouple arm 312 extend in the first direction X1, and the first thermocouple arm 311 and the second thermocouple arm 312 are insulated from each other to avoid interference between the carriers transmitted in the first thermocouple arm 311 and the carriers transmitted in the second thermocouple arm 312, thereby ensuring the generation of a stable electric potential energy from the thermoelectric conversion unit 300. The first thermocouple arm 311 is made of a P-type semiconductor material, and the second thermocouple arm 312 is made of an N-type semiconductor material. That is, when there is a temperature difference between the two ends of the thermocouple arm 310, an electromotive force (voltage) is generated inside the semiconductor material due to the temperature difference, and such a phenomenon is called the Seebeck effect. Specifically, holes in the P-type semiconductor material and electrons in the N-type semiconductor material diffuse from the hot end to the cold end to form a potential difference, thereby generating a current.

Further, referring to FIGS. 3 and 4, the thermoelectric conversion unit 300 further includes a hot-end electrode 320 and a cold-end electrode 330, and the hot-end electrode 320 and the cold-end electrode 330 are located at both sides of the thermocouple arm 310 in the first direction X1. The hot-end electrode 320 and the cold-end electrode 330 are connected to the thermocouple arm 310, respectively. The two thermocouple arms 310 in the thermoelectric conversion unit 300 may be electrically connected to each other through the hot-end electrode 320, thereby achieving the transmission of a current in the thermoelectric conversion unit 300. Two adjacent thermoelectric conversion units 300 may be electrically connected to each other through the cold-end electrode 330, thereby achieving the current transmission between different thermoelectric conversion units 300.

In one or more embodiments, the display panel 10 is placed under sunlight or in the vicinity of a heat source, and specific placement scenes may be adaptively adjusted according to actual requirements, but are not specifically limited in the embodiments of the present disclosure. In the thermoelectric conversion unit 300, an end of the thermocouple arm 310 facing the hot-end electrode 320 is the hot end, and an end of the thermocouple arm 310 facing the cold-end electrode 330 is the cold end. Holes in the first thermocouple arm 311 and electrons in the second thermocouple arm 312 diffuse from the hot end to the cold end to form a potential difference, thereby generating a current.

Specifically, referring to FIGS. 3 and 4, the hot-end electrode 320 is located on a side of the first thermocouple arm 311 and the second thermocouple arm 312 facing away from the base substrate 100, and the cold-end electrode 330 is located on a side of the first thermocouple arm 311 and the second thermocouple arm 312 facing the base substrate 100. In conjunction with FG. 4, the hot-end electrode 320 is in contact with the hot end 310a of the thermocouple arm 310, and the cold-end electrode 330 is in contact with the cold end 310b of the thermocouple arm 310. Further, the thermocouple arm 300 includes a first thermocouple arm 311 and a second thermocouple arm 312, and the hot-end electrode 320 is electrically connected to the first thermocouple arm 311 and the second thermocouple arm 312. The cold-end electrode 330 includes a first cold-end sub-electrode 331 and a second cold-end sub-electrode 332. The first cold-end sub-electrode 331 is electrically connected to the first thermocouple arm 311, and the second cold-end electrode 332 is electrically connected to the second thermocouple arm 312. Further, in order to ensure that the transmission of the generated current is more stable and reliable, the first cold-end sub-electrode 331 and the second cold-end sub-electrode 332 are insulated from each other. The thermoelectric conversion unit 300 includes two thermocouple arms 310, and the corresponding thermoelectric conversion unit 300 includes two cold-end electrodes 330. The number of the thermocouple arms 310 to be provided may correspond to the number of the cold-end electrodes 330 in one-to-one correspondence.

In general, the thermoelectric conversion unit 300 is used to form an electromotive force when there is a temperature difference, and the structure of the thermoelectric conversion unit 300 mainly includes a first thermocouple arm 311, a second thermocouple arm 312, a hot-end electrode 320, and a cold-end electrode 330. In order to better ensure the working efficiency of the thermoelectric conversion unit 300, related structures may also be adaptively added to improve the generation efficiency of electrical energy.

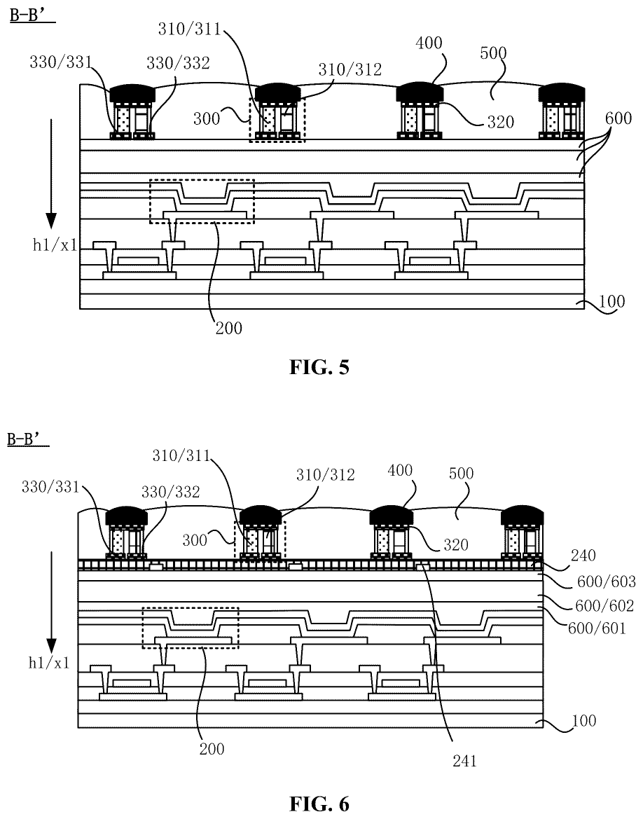

FIG. 5 is a second sectional view of FIG. 2 taken along a section line B-B′. Referring to FIGS. 3 and 5, the display panel 10 further includes multiple black light-absorbing portions 400. The multiple black light-absorbing portions 400 are located at the ends of the thermoelectric conversion units 300 facing away from the base substrate 100 in one-to-one correspondence. The orthographic projection of the thermoelectric conversion unit 300 on the base substrate 100 is located in the orthographic projection of the black light-absorbing portion 400 on the base substrate 100, and the orthographic projection of the black light-absorbing portion 400 on the base substrate 100 does not overlap with the orthographic projection of the light-emitting unit 200 on the base substrate 100.

Further, referring to FIGS. 3 and 5, the display panel 10 further includes multiple black light-absorbing portions 400. The multiple black light-absorbing portions 400 are located at the ends of the thermoelectric conversion units 300 facing away from the base substrate 100. The black light-absorbing portions 400 provided in the display panel 10 may block the transmission of light in one aspect to prevent interference between two adjacent light-emitting units 200 emitting light of different colors, thereby avoiding affecting the overall display performance of the display panel 10. In another aspect, the black light-absorbing portions 400 are made of a black material which has a relatively strong ability to absorb light and heat, and thus, the temperature of the thermoelectric conversion unit 300 at the hot end is raised to increase the temperature difference between the cold end and the hot end of the thermoelectric conversion unit 300, thereby facilitating the formation of an electromotive force.

Further, referring to FIGS. 3 and 5, the orthographic projection of the black light-absorbing portion 400 on the base substrate 100 does not overlap with the orthographic projection of the light-emitting unit 200 on the base substrate 100, that is, the arrangement of the black light-absorbing portions 400 does not interfere with the normal light emission of the light-emitting units 200. Therefore, due to the presence of the black light-absorbing portions 400, the display performance of the display panel 10 is not adversely affected, and further, the light interference between light-emitting units 200 of different colors may be prevented, thereby improving the overall display performance of the display panel 10.

For the orthographic projection of the thermoelectric conversion unit 300 on the base substrate 100 being located in the orthographic projection of the black light-absorbing portion 400 on the base substrate 100, the orthographic projection of the thermoelectric conversion unit 300 on the base substrate 100 coincides with the orthographic projection of the black light-absorbing portion 400 on the base substrate 100, as shown in FIG. 3, or the orthographic projection of the thermoelectric conversion unit 300 on the base substrate 100 is located within the orthographic projection of the black light-absorbing portion 400 on the base substrate 100, as shown in FIG. 5. The size of the black light-absorbing portion 400 may be adaptively adjusted according to requirements and is not specifically limited in the embodiments of the present disclosure.

Still referring to FIGS. 3 and 5, the display panel 10 further includes multiple color resists 500. The multiple color resists 500 are located at light emission sides of the light-emitting units 200 in one-to-one correspondence, and an emitted color of each of the color resists 500 is the same as an emitter color of a respective one of the light-emitting units 200. The orthographic projection of the light-emitting unit 200 on the base substrate 100 is located in the orthographic projection of the color resist 500 on the base substrate 100, and the orthographic projection of the color resist 500 on a plane perpendicular to the base substrate 100 at least partially overlaps with the orthographic projection of the black light-absorbing portion 400 on the plane perpendicular to the base substrate 100.

Referring to FIGS. 3 and 5, the display panel 10 further includes color resists 500, and the color resists 500 are located at the light emission sides of the light-emitting units 200. Since the display panel 10 includes light-emitting units 200 of different colors, in order to ensure the color display performance of the display panel 10, the color resists 500 also have different colors. Specifically, the color of each color resist 500 disposed on a side of the light-emitting units 200 facing away from the base substrate 100 coincides with the color of a corresponding light-emitting unit 200. For example, a color resist 500 correspondingly disposed over a light-emitting unit 200 capable of emitting red light may enable the reflection of red light from ambient light at the color resist 500 while light of other colors is absorbed by the color resist 500. Simultaneously, this color resist 500 does not affect the emission of red light from the light-emitting unit 200, thereby improving the display performance of the display panel 10.

Further, referring to FIGS. 3 and 5, the orthographic projection of the light-emitting unit 200 on the base substrate 100 is located in the orthographic projection of the color resist 500 on the base substrate 100, that is, light emitted from the light-emitting unit 200 is transmitted to the light emission side of the display panel 10 through the color resist 500.

Referring to FIGS. 3 and 5, the orthographic projection of the color resist 500 on the plane perpendicular to the base substrate 100 at least partially overlaps with the orthographic projection of the black light-absorbing portion 400 on the plane perpendicular to the base substrate 100, and the plane perpendicular to the base substrate 100 may also be understood as an extending direction of a plane where the base substrate 100 is located. That is, the color resists 500 and the black light-absorbing portions 400 are disposed in the same layer. Specifically, referring to FIGS. 3 and 5, the thermoelectric conversion units 300 on a side of the black light-absorbing portions 400 facing the base substrate 100 are also disposed in the same layer as the color resists 400. By disposing the film structures in the same layer, the overall film thickness of the display panel 10 may be reduced, thereby facilitating the achievement of a thin design of the display panel 10.

In one or more embodiments, in order to ensure the light emission performance of the light-emitting units 200 in the display panel 10 and prevent ambient light from affecting the overall display performance, a polarizer (not specifically shown in the figure) may be additionally disposed on a side of the light-emitting units 200 facing away from the base substrate 100 in the display panel 10. The polarizer may block the transmission of ambient light while ensuring the emission of light from the light-emitting units 200, thereby ensuring the overall display performance of the display panel 10. In the case where the display panel 10 includes a polarizer, the black light-absorbing portions 400 may be located either on a side of the polarizer facing away from the base substrate 100 or on a side of the polarizer facing the base substrate 100.

In one or more embodiments, referring to FIGS. 3 and 5, the black light-absorbing portion 400 is made of at least one of carbon black, lactam black, perylene black or aniline black.

Specifically, the black light-absorbing portion 400 may be made of an inorganic black material or an organic black material. The inorganic black material may be carbon black, and the organic black material may be at least one of lactam black, perylene black or aniline black. That is, the use of the structure of a black material for the preparation of the black light-absorbing portion 400 may ensure the acquisition of light or heat by the black light-absorbing portion 400, thereby facilitating the formation of an electromotive force by the thermoelectric conversion unit 300.

FIG. 6 is a third sectional view of FIG. 2 taken along a section line B-B′. Referring to FIGS. 2 and 6, the display panel 10 further includes a touch layer 240. The touch layer 240 includes a touch electrode 241. The orthographic projection of the touch electrode 241 on the base substrate 100 does not overlap with the orthographic projection of the light-emitting unit 200 on the base substrate 100 and does not overlap with the orthographic projection of the thermoelectric conversion unit 300 on the base substrate 100.

Further, referring to FIG. 6, the display panel 10 further includes a touch layer 240, and a touch electrode 241 is disposed in the touch layer 240. The display panel 10 achieves a touch function through the touch electrode 241. Only one layer of the touch layer 240 is illustrated as an example in FIG. 6. The specific number of film layers in the touch layer 240 may be adjusted according to requirements. For example, the touch layer 240 includes a touch blocking layer and a touch encapsulation layer. The specific number of film layers in the touch layer 240 is not specifically limited in the embodiments of the present disclosure.

Further, referring to FIG. 6, the orthographic projection of the touch electrode 241 on the base substrate 100 does not overlap with the orthographic projection of the light-emitting unit 200 on the base substrate 100 to prevent the touch electrode 241 from interfering with the display performance of the display panel 10, thereby ensuring the display performance of the display panel 10. Further, the orthographic projection of the touch electrode 241 on the base substrate 100 does not overlap with the orthographic projection of the thermoelectric conversion unit 300 on the base substrate 100 so that the acquisition of a touch signal by the touch electrode 241 is more accurately and the thermoelectric conversion unit 300 is prevented from interfering with the acquisition and response of the touch signal, thereby ensuring the touch performance of the display panel 10.

It is to be noted that the number of touch electrodes 241 in the display panel 10 does not need to correspond one-to-one with the number of light-emitting units 200. In FIG. 6, for the purpose of illustrating the location relationship between the touch electrodes 241, the thermoelectric conversion units 300 and the light-emitting units 200, each light-emitting unit 200 is depicted with a touch electrode 241 nearby. That is, a touch electrode 241 may or may not be disposed near a light-emitting unit 200. The specific arrangement of the touch electrode 241 depends on the overall array layout in the display panel 10.

Further, the orthographic projections of the touch electrodes 241 on the base substrate 100 in the display panel 10 have the same area or similar areas so that the touch response of the display panel 10 and the transmission of the touch signal may be balanced and stable, thereby ensuring the touch performance of the display panel 10.

In one or more embodiments, referring to FIG. 6, the display panel 10 may further include a thin-film encapsulation layer 600, and the thin-film encapsulation layer 600 may include a first inorganic layer 601, a first organic layer 602 and a third inorganic layer 603 arranged sequentially in the thickness direction of the base substrate 100. The arrangement of the thin-film encapsulation 10 may achieve the protection for the display panel 100 and ensure the overall flatness of the display panel 10. The touch layer 240 may be disposed on a side of the thin-film encapsulation layer 600 facing away from the base substrate 100, and the color resists 500, the black light-absorbing portions 400 and the thermoelectric conversion units 300 are all located on a side of the touch layer 240 facing away from the base substrate 100. By disposing the color resists 500 and the black light-absorbing portions 400 on a side of the touch layer 240 facing away from the base substrate 100, a “Color Filter On Touch (CFOT)” structure of the display panel 10 may be achieved.

Still referring to FIG. 6, in a direction perpendicular to the base substrate 100, the touch layer 240 is located between a film layer where the multiple thermoelectric conversion units 300 are located and a film layer where the multiple light-emitting units 200 are located.

Further, referring to FIG. 6, in a direction perpendicular to the base substrate 100, the touch layer 240 is located between the film layer where the multiple thermoelectric conversion units 300 are located and the film layer where the multiple light-emitting units 200 are located, that is, the touch electrodes 241 in the touch layer 240 and the light-emitting units 200 are disposed in different layers, thereby ensuring the stability of the display function and the touch function of the display panel 10. The touch electrodes 241 in the touch layer 240 and the thermoelectric conversion units 300 are also disposed in different layers to avoid interference between the transmission of the touch signals and the electromotive forces generated by the thermoelectric conversion units 300, thereby ensuring the stability of the display panel 10. Specifically, the multiple touch electrodes 241 in the display panel 10 are connected through a touch wire (not specifically shown in the figure), and a connection wire is also required to transmit the electric energy generated by the thermoelectric conversion units 300 to the power module of the display panel 10. Therefore, the arrangement of the touch electrodes 241 and the thermoelectric conversion units 300 in different layers may ensure the stability and reliability of signal transmission.

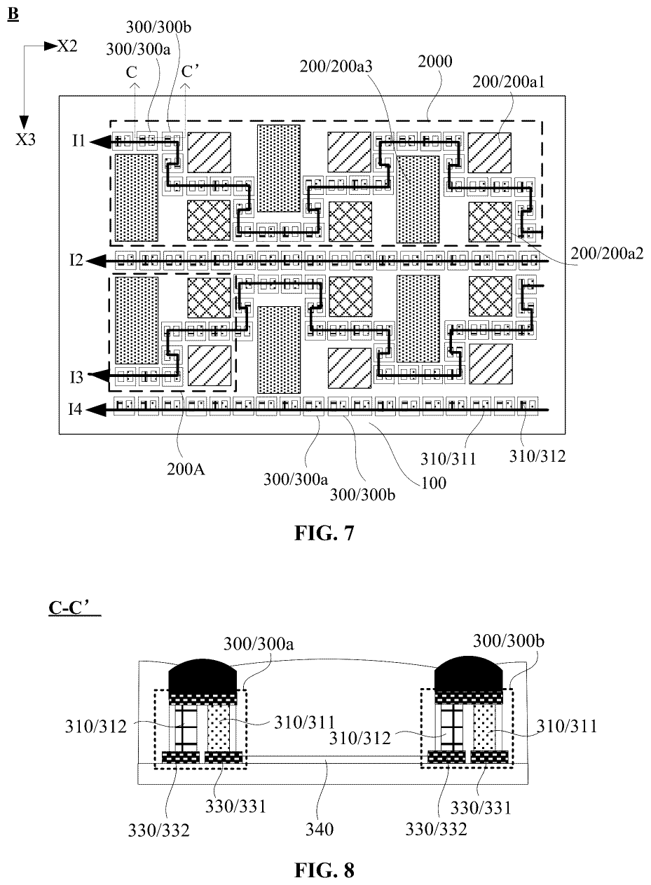

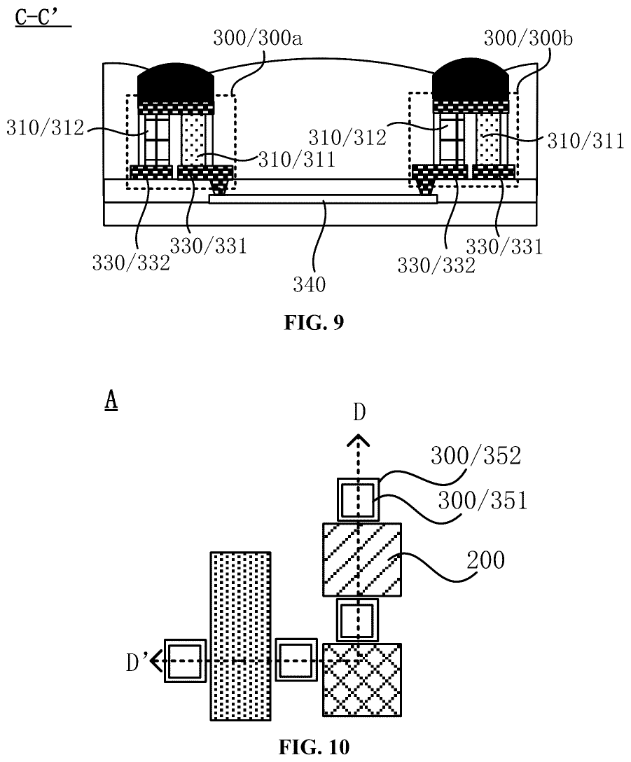

FIG. 7 is a first enlarged view of region B in FIG. 1, FIG. 8 is a sectional view of FIG. 7 taken along a section line C-C′, and FIG. 9 is a second sectional view of FIG. 7 taken along a section line C-C′. Referring to FIGS. 1, 7 and 9, multiple thermoelectric conversion units 300 are sequentially connected in series to form a series branch. In the series branch, two adjacent thermoelectric conversion units 300 include a first sub-thermoelectric conversion unit 300a and a second sub-thermoelectric conversion unit 300b. A first cold-end sub-electrode 331 of the first sub-thermoelectric conversion unit 300a is electrically connected to a second cold-end sub-electrode 332 of the second sub-thermoelectric conversion unit 300b.

Specifically, referring to FIG. 7, the display panel 10 includes multiple thermoelectric conversion units 300, and the multiple thermoelectric conversion units 300 are sequentially connected in series to form a series branch. For example, referring to FIG. 7, I1, I2, I3 and I4 in FIG. 7 may be understood as the current flow directions in the branches formed by multiple thermoelectric conversion units 300. It is to be noted that the solid lines in FIG. 7 are used to clearly illustrate the current flow directions, but the actual product does not include these solid lines. Further, referring to FIG. 7, in the series branch, two adjacent thermoelectric conversion units 300 include a first sub-thermoelectric conversion unit 300a and a second sub-thermoelectric conversion unit 300b. The first sub-thermoelectric conversion unit 300a and the second sub-thermoelectric conversion unit 300b are connected to enable the current generated by the thermoelectric conversion units 300 to be sequentially transmitted and further delivered to the power module of the display panel 10, thereby increasing the endurance time of the display panel 10.

Specifically, referring to FIGS. 8 and 9, a first cold-end sub-electrode 331 of the first sub-thermoelectric conversion unit 300a is electrically connected to a second cold-end sub-electrode 332 of the second sub-thermoelectric conversion unit 300b. Further, referring to FIGS. 8 and 9, the first cold-end sub-electrode 331 of the first sub-thermoelectric conversion unit 300a is electrically connected to the second cold-end sub-electrode 332 of the second sub-thermoelectric conversion unit 300b through a connection wire 340. The first cold-end sub-electrodes 331, the second cold-end sub-electrodes 332 and the connection wire 340 being disposed in the same layer is illustrated as an example in FIG. 8, and the first cold-end sub-electrodes 331, the second cold-end sub-electrodes 332 and the connection wire 340 being disposed in different layers is illustrated as an example in FIG. 9. The location of the connection wire 340 to be disposed may be adaptively adjusted according to requirements and is not specifically limited in the embodiments of the present disclosure.

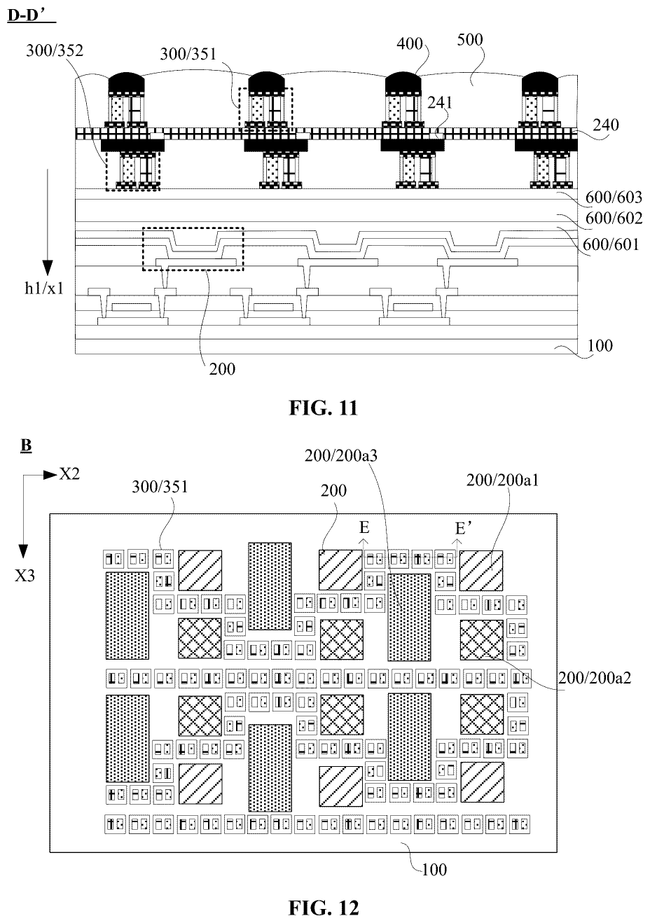

FIG. 10 is a second enlarged view of region A in FIG. 1, and FIG. 11 is a first sectional view of FIG. 10 taken along a section line D-D′. Referring to FIGS. 10 and 11, the multiple thermoelectric conversion units 300 include multiple first thermoelectric conversion units 351 and multiple second thermoelectric conversion units 352. The multiple first thermoelectric conversion units 351 are located in the same film layer, and the multiple second thermoelectric conversion units 352 are located in the same film layer. In a direction perpendicular to the base substrate 100 and facing away from the base substrate 100, the film layer where the light-emitting units 200 are located, the film layer where the second thermoelectric conversion units 352 are located, the touch layer 240 and the film layer where the first thermoelectric conversion units 351 are located are sequentially arranged.

Further, the multiple thermoelectric conversion units 300 are arranged in the display panel 10 in diverse manners. Referring to FIGS. 3, 5, 6 and 7 to 9, the multiple thermoelectric conversion units 300 are all disposed in the same film layer; or, referring to FIG. 10, the multiple thermoelectric conversion units 300 may be disposed in different film layers in the display panel 10. Therefore, the arrangement manner of the thermoelectric conversion units 300 varies and may be adaptively adjusted according to requirements of different display panels 10.

Referring to FIG. 10, the multiple thermoelectric conversion units 300 include multiple first thermoelectric conversion units 351 and multiple second thermoelectric conversion units 352. The multiple first thermoelectric conversion units 351 are located in the same layer, and the multiple second thermoelectric conversion units 352 are located in the same layer. The multiple first thermoelectric conversion units 351 and the multiple second thermoelectric conversion units 352 may be disposed in different layers. Therefore, more thermoelectric conversion units 300 may be added to the display panel 10, thereby improving the efficiency of the electromotive force generated by the thermoelectric conversion units 300 and better increasing the endurance time of the display panel 10.

Specifically, referring to FIG. 10, in a direction perpendicular to the base substrate 100 and facing away from the base substrate 100, the film layer where the light-emitting units 200 are located, the film layer where the second thermoelectric conversion units 352 are located, the touch layer 240 and the film layer where the first thermoelectric conversion units 351 are located are sequentially arranged. It is also to be understood that the film layer where the light-emitting units 200 are located is located on a side of the base substrate 100, the film layer where the second thermoelectric conversion units 352 are located is located on a side of the film layer where the light-emitting units 200 are located facing away from the base substrate 100, and a thin-film encapsulation layer 600 may be added between the film layer where the light-emitting units 200 are located and the film layer where the second thermoelectric conversion units 352 are located. Further, the touch layer 240 is located on a side of the film layer where the second thermoelectric conversion units 352 are located facing away from the film layer where the light-emitting units 200 are located, and the film layer where the first thermoelectric conversion units 351 are located is located on a side of the touch layer 240 facing away from the film layer where the second thermoelectric conversion units 352 are located.

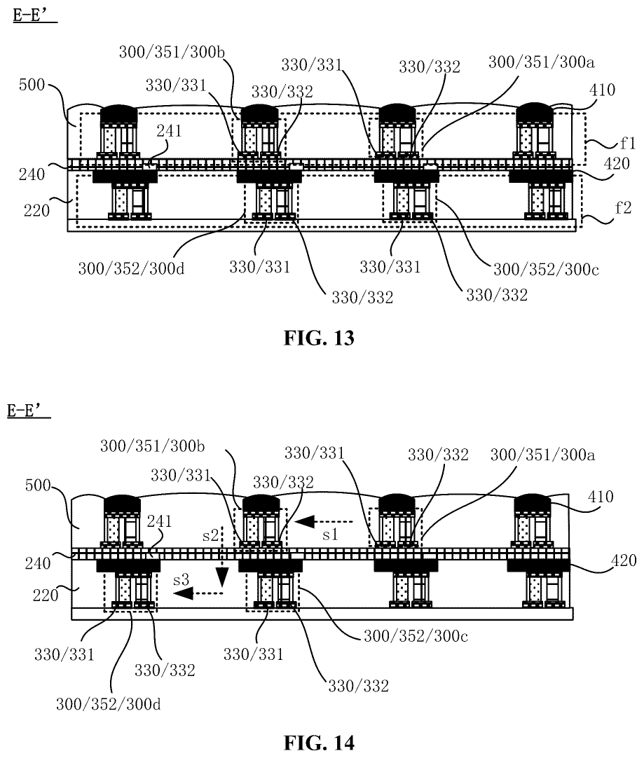

FIG. 12 is a second enlarged view of region B in FIG. 1, and FIG. 13 is a first sectional view of FIG. 12 taken along a section line E-E′. Referring to FIGS. 12 and 13, multiple first thermoelectric conversion units 351 are sequentially connected in series to form a first series branch f1. In the first series branch f1, two adjacent first thermoelectric conversion units 351 include a first sub-thermoelectric conversion unit 300a and a second sub-thermoelectric conversion unit 300b. A first cold-end sub-electrode 331 of the first sub-thermoelectric conversion unit 300a is electrically connected to a second cold-end sub-electrode 332 of the second sub-thermoelectric conversion unit 300b. Multiple second thermoelectric conversion units 352 are sequentially connected in series to form a second series branch f2. In the second series branch f2, two adjacent second thermoelectric conversion units 352 include a third sub-thermoelectric conversion unit 300c and a fourth sub-thermoelectric conversion unit 300d. A first cold-end sub-electrode 331 of the third sub-thermoelectric conversion unit 300c is electrically connected to a second cold-end sub-electrode 332 of the fourth sub-thermoelectric conversion unit 300d.

Multiple first thermoelectric conversion units 351 are sequentially connected in series to form the first series branch f1, and part of the first thermoelectric conversion units 351 in the first series branch f1 are illustrated in FIG. 13. In FIG. 13, only four first thermoelectric conversion units 351 in the first series branch f1 are illustrated. The number of first thermoelectric conversion units 351 to be disposed in the first series branch f1 may be adaptively adjusted according to requirements. Similarly, multiple second thermoelectric conversion units 352 are sequentially connected in series to form the second series branch f2, and part of the second thermoelectric conversion units 352 in the second series branch f2 are illustrated in FIG. 13. In FIG. 13, only four second thermoelectric conversion units 352 in the second series branch f2 are illustrated. The number of second thermoelectric conversion units 352 to be disposed in the second series branch f2 may be adaptively adjusted according to requirements.

Further, referring to FIG. 13, the first series branch f1, two adjacent first thermoelectric conversion units 351 include a first sub-thermoelectric conversion unit 300a and a second sub-thermoelectric conversion unit 300b, and the first sub-thermoelectric conversion unit 300a is electrically connected to the second sub-thermoelectric conversion unit 300b. Specifically, referring to FIG. 13, the first cold-end sub-electrode 331 of the first sub-thermoelectric conversion unit 300a is electrically connected to the second cold-end sub-electrode 332 of the second sub-thermoelectric conversion unit 300b to achieve the series connection of multiple first thermoelectric conversion units 351, thereby enabling the transmission of the generated electrical energy and increasing the endurance time of the display panel 10.

Further, referring to FIG. 13, the second series branch f2, two adjacent second thermoelectric conversion units 352 include a third sub-thermoelectric conversion unit 300c and a fourth sub-thermoelectric conversion unit 300d, and the third sub-thermoelectric conversion unit 300c is electrically connected to the fourth sub-thermoelectric conversion unit 300d. Specifically, referring to FIG. 13, the first cold-end sub-electrode 331 of the third sub-thermoelectric conversion unit 300c is electrically connected to the second cold-end sub-electrode 332 of the fourth sub-thermoelectric conversion unit 300d to achieve the series connection of multiple second thermoelectric conversion units 352, thereby enabling the transmission of the generated electrical energy and increasing the endurance time of the display panel 10.

It is to be noted that the thermoelectric conversion units 300 included in the display panel 10 are disposed in the same layer in FIG. 7, and the thermoelectric conversion units 300 included in the display panel 10 may be disposed in different layers in FIG. 12. In FIG. 12, at least part of the second thermoelectric conversion units 352 are shielded by the first thermoelectric conversion units 351, so only the first thermoelectric conversion units 351 are illustrated in FIG. 12.

FIG. 14 is a second sectional view of FIG. 12 taken along a section line E-E′. Referring to FIGS. 12 and 14, multiple first thermoelectric conversion units 351 and multiple second thermoelectric conversion units 352 are sequentially connected in series to form a series branch. In the series branch, two adjacent first thermoelectric conversion units 351 include a first sub-thermoelectric conversion unit 300a and a second sub-thermoelectric conversion unit 300b, two adjacent second thermoelectric conversion units 352 include a third sub-thermoelectric conversion unit 300c and a fourth sub-thermoelectric conversion unit 300d, and the second sub-thermoelectric conversion unit 300b is adjacent to the third sub-thermoelectric conversion unit 300c. The first cold-end sub-electrode 331 of the first sub-thermoelectric conversion unit 300a is electrically connected to the second cold-end sub-electrode 332 of the second sub-thermoelectric conversion unit 300b, the first cold-end sub-electrode 331 of the second sub-thermoelectric conversion unit 300b is electrically connected to the second cold-end sub-electrode 332 of the third sub-thermoelectric conversion unit 300c, and the first cold-end sub-electrode 331 of the third sub-thermoelectric conversion unit 300c is electrically connected to the second cold-end sub-electrode 332 of the fourth sub-thermoelectric conversion unit 300d.

Referring to FIG. 14, the multiple first thermoelectric conversion units 351 and the multiple second thermoelectric conversion units 352 are disposed in different film layers of the display panel 10, respectively. The multiple first thermoelectric conversion units 351 and the multiple second thermoelectric conversion units 352 may form one series branch to transmit the electric energy generated by the thermoelectric conversion units 300 to the display panel 10, thereby increasing the endurance time of the display panel 10.

Specifically, referring to FIG. 14, two adjacent first thermoelectric conversion units 351 include a first sub-thermoelectric conversion unit 300a and a second sub-thermoelectric conversion unit 300b, two adjacent second thermoelectric conversion units 352 include a third sub-thermoelectric conversion unit 300c and a fourth sub-thermoelectric conversion unit 300d, and the second sub-thermoelectric conversion unit 300b and the third sub-thermoelectric conversion unit 300c, which are disposed in different layers, are also adjacent to each other. Therefore, the first sub-thermoelectric conversion unit 300a, the second sub-thermoelectric conversion unit 300b, the third sub-thermoelectric conversion unit 300c and the fourth sub-thermoelectric conversion unit 300d are sequentially connected in series, thereby achieving the current transmission. Referring to FIG. 14, the current transmitted to the first sub-thermoelectric conversion unit 300a may be transmitted to the second sub-thermoelectric conversion unit 300b (refer to the current wire s1 in FIG. 14), the current transmitted to the second sub-thermoelectric conversion unit 300b may be transmitted to the third sub-thermoelectric conversion unit 300c (refer to the current wire s2 in FIG. 14), and the current transmitted to the third sub-thermoelectric conversion unit 300c may then be transmitted to the fourth sub-thermoelectric conversion unit 300d (refer to the current wire s3 in FIG. 14). Therefore, the multiple thermoelectric conversion units 300 are connected in a serpentine manner, manifesting the diversity of the connection manner of the thermoelectric conversion units 300.

Specifically, referring to FIG. 14, the first cold-end sub-electrode 331 of the first sub-thermoelectric conversion unit 300a is electrically connected to the second cold-end sub-electrode 332 of the second sub-thermoelectric conversion unit 300b in the same layer, the first cold-end sub-electrode 331 of the second sub-thermoelectric conversion unit 300b is electrically connected to the second cold-end sub-electrode 332 of the third sub-thermoelectric conversion unit 300c across layers, and the first cold-end sub-electrode 331 of the third sub-thermoelectric conversion unit 300c is electrically connected to the second cold-end sub-electrode 332 of the fourth sub-thermoelectric conversion unit 300d in the same layer.

Still referring to FIGS. 13 and 14, the display panel 10 further includes multiple first black light-absorbing portions 410 and multiple second black light-absorbing portions 420. The multiple first black light-absorbing portions 410 are located at terminals of the first thermoelectric conversion units 351 facing away from the base substrate 100 in one-to-one correspondence. The orthographic projection of the first thermoelectric conversion unit 351 on the base substrate 100 is located in the orthographic projection of the first black light-absorbing portion 410 on the base substrate 100, and the orthographic projection of the first black light-absorbing portion 410 on the base substrate 100 does not overlap with the orthographic projection of the light-emitting unit 200 on the base substrate 100. The multiple second black light-absorbing portions 420 are located at terminals of the multiple second thermoelectric conversion units 352 facing away from the base substrate 100 in one-to-one correspondence. The orthographic projection of the second thermoelectric conversion unit 352 on the base substrate is located in the orthographic projection of the second black light-absorbing portion 420 on the base substrate 100, and the orthographic projection of the second black light-absorbing portion 420 on the base substrate 100 does not overlap with the orthographic projection of the light-emitting unit 200 on the base substrate 100.

Further, referring to FIGS. 13 and 14, the display panel 10 includes multiple first black light-absorbing portions 410 and multiple second black light-absorbing portions 420. The multiple first black light-absorbing portions 410 and the multiple second black light-absorbing portions 420 are all located on a side of the thermoelectric conversion units 300 facing away from the base substrate 100. The arrangement of the first black light-absorbing portions 410 and the second black light-absorbing portions 420 may block the transmission of light in one aspect to prevent interference between two adjacent light-emitting units 200 emitting light of different colors, thereby avoiding affecting the overall display performance of the display panel 10. In another aspect, the black light-absorbing portions 400 are made of a black material which has a relatively strong ability to absorb light and heat, and thus, the temperature of the thermoelectric conversion unit 300 at the hot end is raised to increase the temperature difference between the cold end and the hot end of the thermoelectric conversion unit 300, thereby facilitating the formation of an electromotive force.

Specifically, the first black light-absorbing portion 410 is located on a side of the first thermoelectric conversion unit 351 facing away from the base substrate 100, and the heat absorbed by the first black light-absorbing portion 410 is transferred to the first thermoelectric conversion unit 351. The orthographic projection of the first thermoelectric conversion unit 351 on the base substrate 100 is located in the orthographic projection of the first black light-absorbing portion 410 on the base substrate 100, that is, the first thermoelectric conversion unit 351 is covered by the first black light-absorbing portion 410. Further, the orthographic projection of the first black light-absorbing portion 410 on the base substrate 100 does not overlap with the orthographic projection of the light-emitting unit 200 on the base substrate 100, that is, the arrangement of the first black light-absorbing portions 410 does not affect the light-emitting display of the light-emitting units 200 so that the arrangement of the first black light-absorbing portions 410 does not affect the normal display of the display panel 10.

Specifically, the second black light-absorbing portion 420 is located on a side of the second thermoelectric conversion unit 352 facing away from the base substrate 100, and the heat absorbed by the second black light-absorbing portion 420 is transferred to the second thermoelectric conversion unit 352. The orthographic projection of the second thermoelectric conversion unit 352 on the base substrate 100 is located in the orthographic projection of the second black light-absorbing portion 420 on the base substrate 100, that is, the second thermoelectric conversion unit 352 is covered by the second black light-absorbing portion 420. Further, the orthographic projection of the second black light-absorbing portion 420 on the base substrate 100 does not overlap with the orthographic projection of the light-emitting unit 200 on the base substrate 100, that is, the arrangement of the second black light-absorbing portions 420 does not affect the light-emitting display of the light-emitting units 200 so that the arrangement of the second black light-absorbing portions 420 does not affect the normal display of the display panel 10.

Further, the first thermoelectric conversion unit 351 is located on a side of the second thermoelectric conversion unit 352 facing away from the base substrate 100, that is, the first thermoelectric conversion unit 351 is closer to the light emission side of the display panel 10, so that the first black light-absorbing portion 410 at the first thermoelectric conversion unit 341 and the adjacent color resistor 500 are configured in a convex shape. Setting the color resistor 500 as a convex shape may enhance light output efficiency, and setting the first black light-absorbing portion 410 as a convex shape may improve heat absorption efficiency, thereby increasing the working efficiency of the first thermoelectric conversion unit 351. The second black light-absorbing portion 420 at the second thermoelectric conversion unit 352 is located within the film layer of the display panel 10. In order to ensure the overall flatness of the display panel 10, the surface of the second black light-absorbing portion 420 is made relatively even.

Still referring to FIGS. 13 and 14, the area of the orthographic projection of the first black light-absorbing portion 410 on the base substrate 100 is smaller than the area of the orthographic projection of the second black light-absorbing portion 420 on the base substrate 100, and the orthographic projection of at least one first black light-absorbing portion 410 on the base substrate 100 and the orthographic projection of the touch electrode 241 on the base substrate 100 are located in the orthographic projection of the same second black light-absorbing portion 420 on the base substrate 100.

The first black light-absorbing portion 410 is located on a side of the second light-absorbing portion 420 facing away from the base substrate 100. In an extending direction of the base substrate 100, a color resistor 500 may be disposed between two adjacent first black light-absorbing portions 410 to improve the color display performance of the display panel 10, and an insulating layer 220 may be disposed between two adjacent second black light-absorbing portions 420 to prevent short circuits between different thermoelectric conversion units 300. Therefore, compared to the arrangement location of the second black light-absorbing portion 420, the arrangement location of the first black light-absorbing portion 410 has a more direct impact on the light emission performance of the display panel 10. In order to avoid compromising the display performance of the display panel 10 due to the presence of the first black light-absorbing portion 410, the area of the first black light-absorbing portion 410 is designed to be relatively smaller. Further, in order to increase the heat supplied to the thermoelectric conversion unit 300, the area of the second black light-absorbing portion 420 may be made relatively larger, provided that the orthographic projection of the second black light-absorbing portion 420 on the base substrate 100 does not overlap with the orthographic projection of the light-emitting unit 200 on the base substrate 100. That is, by adjusting the area of the orthographic projection of the first black light-absorbing portion 410 on the base substrate 100 to be smaller than the area of the orthographic projection of the second black light-absorbing portion 420 on the base substrate 100, the working efficiency of the thermoelectric conversion unit 300 may be improved without adversely affecting the light emission performance of the display panel 10.

Further, the touch electrode 241 is disposed on a side of the first black light-absorbing portion 410 facing the second black light-absorbing portion 420. Since the area of the orthographic projection of the second black light-absorbing portion 420 on the base substrate 100 is larger than the area of the orthographic projection of the first black light-absorbing portion 410 on the base substrate 100, the additional area of the second black light-absorbing portion 420 beyond the first black light-absorbing portion 410 may be used to arranged the touch electrode 241, thereby facilitating the enhancement of space utilization of various components in the display panel 10 and improving the overall display performance of the display panel 10.

Referring to FIG. 7, at least two light-emitting units 200 of different emitted colors form one pixel unit 200A, multiple pixel units 200A sequentially arranged in a second direction X2 form a pixel unit row 2000, and multiple pixel unit rows 2000 are sequentially arranged in a third direction X3, where the second direction X2 and the third direction X3 are parallel to the base substrate 100 and intersect with each other. In the orthographic projection of the base substrate 100, at least part of the thermoelectric conversion units 300 are located between adjacent pixel unit rows 2000 and sequentially connected in series to form a series branch, and series branches between different adjacent pixel unit rows 2000 are connected in parallel. In the series branch, two adjacent thermoelectric conversion units 300 include a first sub-thermoelectric conversion unit 300a and a second sub-thermoelectric conversion unit 300b, and the first cold-end sub-electrode 331 of the first sub-thermoelectric conversion unit 300a is electrically connected to the second cold-end sub-electrode 332 of the second sub-thermoelectric conversion unit 300b.

Further, referring to FIG. 7, light-emitting units 200 of different emitted colors form one pixel unit 200A. FIG. 7 illustrates an example where light-emitting units 200 of three different emitted colors form one pixel unit 200A. Additionally, multiple pixel units 200A sequentially arranged in the second direction X2 form a pixel unit row 2000, and multiple pixel unit rows 2000 are sequentially arranged in the third direction X3, thereby achieving the array layout of the multiple light-emitting units 200 in the display panel 10.

Further, the orthographic projections of at least part of the thermoelectric conversion units 300 on the base substrate 100 are located between two adjacent pixel unit rows 2000, and these thermoelectric conversion units 300 are connected in series to form a corresponding series branch. Referring to FIGS. 7, 12 and 14 in FIG. 7 may be understood as the current flow directions in such series branches formed by multiple thermoelectric conversion units 300, respectively. The multiple thermoelectric conversion units 300 forming the current flow direction I2 in the series branch are located between adjacent pixel unit rows 2000. The multiple thermoelectric conversion units 300 are interconnected to form a series circuit, and the series branches between different adjacent pixel unit rows 2000 are connected in parallel. In other words, the multiple thermoelectric conversion units 300 first increase the voltage through horizontal series connections and then increase the current through vertical parallel connections to enhance the overall ability of the thermoelectric conversion units 300 to supply a greater current to the display panel 10, thereby further increasing the endurance time of the display panel 10.

Further, referring to FIG. 7, with the series branch (with the current flow direction I2) formed by multiple thermoelectric conversion units 300 as an example, two adjacent thermoelectric conversion units 300 include a first sub-thermoelectric conversion unit 300a and a second sub-thermoelectric conversion unit 300b. Correspondingly, referring to FIGS. 8 and 9, the first cold-end sub-electrode 331 of the first sub-thermoelectric conversion unit 300a is electrically connected to the second cold-end sub-electrode 332 of the second sub-thermoelectric conversion unit 300b. The same principle applies to the series branch (with the current flow direction I4) formed by multiple thermoelectric conversion units 300 in FIG. 7, which will not be repeated here.

In one or more embodiments, the arrangement manner of the light-emitting units 200 in the display panel 10 varies and is not limited to the configuration shown in FIG. 7. In other arrangement manners of the light-emitting units 200, multiple thermoelectric conversion units 300 may similarly be disposed between the pixel unit rows 2000 formed by multiple light-emitting units 200. Not all arrangement configurations of the various display panels 10 are individually illustrated here.

Referring to FIGS. 7 to 9, at least two light-emitting units 200 of different emitted colors form one pixel unit 200A, multiple pixel units 200A sequentially arranged in the second direction X2 form a pixel unit row 2000, and multiple pixel unit rows 2000 are sequentially arranged in the third direction X3, where the second direction X2 and the third direction X3 are parallel to the base substrate 100 and intersect with each other. In the orthographic projection of the base substrate 100, at least part of the thermoelectric conversion units 300 are located between adjacent light-emitting units 200 in the pixel unit row 2000 and sequentially connected in series to form a series branch, and series branches in different adjacent pixel unit rows 2000 are connected in parallel. In the series branch, two adjacent thermoelectric conversion units 300 include a first sub-thermoelectric conversion unit 300a and a second sub-thermoelectric conversion unit 300b, and the first cold-end sub-electrode 331 of the first sub-thermoelectric conversion unit 300a is electrically connected to the second cold-end sub-electrode 332 of the second sub-thermoelectric conversion unit 300b.

Further, referring to FIG. 7, light-emitting units 200 of different emitted colors form one pixel unit 200A, and FIG. 7 illustrates an example where light-emitting units 200 of three different emitted colors form one pixel unit 200A. Additionally, multiple pixel units 200A sequentially arranged in the second direction X2 form a pixel unit row 2000, and multiple pixel unit rows 2000 are sequentially arranged in the third direction X3, thereby achieving the array layout of the multiple light-emitting units 200 in the display panel 10.

Further, the orthographic projections of at least part of the thermoelectric conversion units 300 on the base substrate 100 are located between adjacent light-emitting units 200 in the pixel unit row 2000, and these thermoelectric conversion units 300 are connected in series to form a corresponding series branch. Referring to FIG. 7, I1 and I3 in FIG. 7 may be understood as the current flow directions in such series branches formed by multiple thermoelectric conversion units 300, respectively. The multiple thermoelectric conversion units 300 forming the current flow direction I1 in the series branch are located between adjacent light-emitting units 200 in the pixel unit row 2000. The multiple thermoelectric conversion units 300 are interconnected to form a series circuit, and multiple formed series branches are connected in parallel. In other words, the multiple thermoelectric conversion units 300 first increase the voltage through horizontal series connections and then increase the current through vertical parallel connections to enhance the overall ability of the thermoelectric conversion units 300 to supply a greater current to the display panel 10, thereby further increasing the endurance time of the display panel 10. That is, the thermoelectric conversion units 300 may be disposed not only between pixel unit rows 2000 but also between light-emitting units 200 in pixel unit rows 2000.

Further, referring to FIG. 7, with the series branch (with the current flow direction I1) formed by multiple thermoelectric conversion units 300 as an example, two adjacent thermoelectric conversion units 300 include a first sub-thermoelectric conversion unit 300a and a second sub-thermoelectric conversion unit 300b. Correspondingly, referring to FIGS. 8 and 9, the first cold-end sub-electrode 331 of the first sub-thermoelectric conversion unit 300a is electrically connected to the second cold-end sub-electrode 332 of the second sub-thermoelectric conversion unit 300b. The same principle applies to the series branch (with the current flow direction I3) formed by multiple thermoelectric conversion units 300 in FIG. 7, which will not be repeated here.

In one or more embodiments, the arrangement manner of the light-emitting units 200 in the display panel 10 varies and is not limited to the configuration shown in FIG. 7. In other arrangement manners of the light-emitting units 200, multiple thermoelectric conversion units 300 may similarly be disposed between the pixel unit rows 2000 formed by multiple light-emitting units 200. Not all arrangement configurations of the various display panels 10 are individually illustrated here.

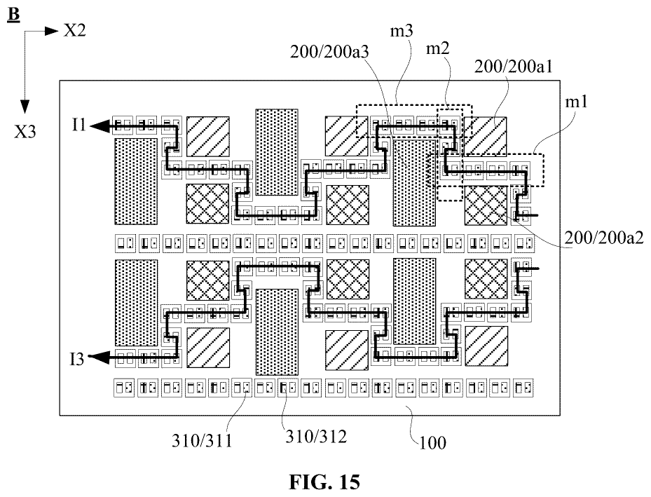

FIG. 15 is a third enlarged view of region B in FIG. 1. Referring to FIG. 5, the pixel unit 200A includes a first light-emitting unit 200a1, a second light-emitting unit 200a2 and a third light-emitting unit 200a3, and the first light-emitting unit 200a1, the second light-emitting unit 200a2 and the third light-emitting unit 200a3 have different emitted colors. The first light-emitting unit 200a1 and the second light-emitting unit 200a2 are arranged in the third direction X3, and the combination of the first light-emitting unit 200a1 and the second light-emitting unit 200a2 and the third light-emitting unit 200a3 are alternately arranged in the second direction X2. The series branch includes multiple first series sub-branches m1, multiple second series sub-branches m2 and multiple third series sub-branches m3. The first series sub-branch m1 is located between the first light-emitting unit 200a1 and the second light-emitting unit 200a2, and the thermoelectric conversion units 300 in the first series sub-branch m1 are sequentially arranged in the second direction X2. The second series sub-branch m2 is located between the combination of the first light-emitting unit 200a1 and the second light-emitting unit 200a2 and the third light-emitting unit 200a3, and the thermoelectric conversion units 300 in the second series sub-branch m2 are sequentially arranged in the third direction X3. The third series sub-branch m3 and the third light-emitting unit 200a3 are arranged in the third direction X3, and two adjacent third light-emitting units 200a3 and corresponding third series sub-branches m3 are arranged in an alternating positional orientation along the third direction X3.

Further, referring to FIGS. 7 and 15, the pixel unit 200A includes multiple light-emitting units 200 of different emitted colors. Specifically, the pixel unit 200A includes a first light-emitting unit 200a1, a second light-emitting unit 200a2 and a third light-emitting unit 200a3. For example, the first light-emitting unit 200a1 may emit red light, the second light-emitting unit 200a2 may emit green light, and the third light-emitting unit 200a3 may emit blue light. The array arrangement of the light-emitting units 200 of different emitted colors enables the color display performance of the display panel 10.

Further, referring to FIG. 7, in the pixel unit 200A, the first light-emitting unit 200a1 and the second light-emitting unit 200a2 are arranged in the third direction X3, and the combinations of the first light-emitting unit 200a1 and the second light-emitting unit 200a2 are arranged in the second direction X2. A third light-emitting unit 200a3 is disposed between two adjacent combinations of the first light-emitting unit 200a1 and the second light-emitting unit 200a2.

Further, the thermoelectric conversion unit 300 may be disposed between the light-emitting units 200 in the pixel unit row 2000, that is, multiple thermoelectric conversion units 300 may be disposed among the first light-emitting unit 200a1, the second light-emitting unit 200a2 and the third light-emitting unit 200a3, which emit different colors, in the pixel unit 200A. Specifically, referring to FIGS. 7 and 15, I1 and I3 may be understood as the current flow directions in series branches formed by multiple thermoelectric conversion units 300, respectively. Further, referring to FIG. 15, with the series branch forming the current flow direction I1 as an example, the series branch includes multiple first series sub-branches m1, multiple second series sub-branches m2 and multiple third series sub-branches m3. The first series sub-branches m1, the second series sub-branches m2 and the third series sub-branches m3 are disposed between different light-emitting units 200 and achieve the current transmission through the electrical interconnections.

Specifically, referring to FIG. 7, the first series sub-branch m1 is located between the first light-emitting unit 200a1 and the second light-emitting unit 200a2, and multiple thermoelectric conversion units 300 in the first series sub-branch m1 are sequentially arranged in the second direction X2. The first series sub-branch m1 is connected in series to the second series sub-branch m2. The second series sub-branch m2 is located between the combination of the first light-emitting unit 200a1 and the second light-emitting unit 200a2 and the third light-emitting unit 200a3, and multiple thermoelectric conversion units 300 in the second series sub-branch m2 are sequentially arranged in the third direction X3. The second series sub-branch m2 is connected in series to the third series sub-branch m3, and the third series sub-branch m3 and the third light-emitting unit 200a3 are arranged in the third direction X3. Further, referring to FIG. 7, two adjacent third light-emitting units 200a3 and corresponding third series sub-branches m3 are arranged in an alternating positional orientation along the third direction X3. That is, for two adjacent third light-emitting units 200a3, the direction in which one third light-emitting unit 200a3 points to the corresponding closest third series sub-branch m3 is opposite to the direction in which the other third light-emitting unit 200a3 points to the corresponding closest third series sub-branch m3.

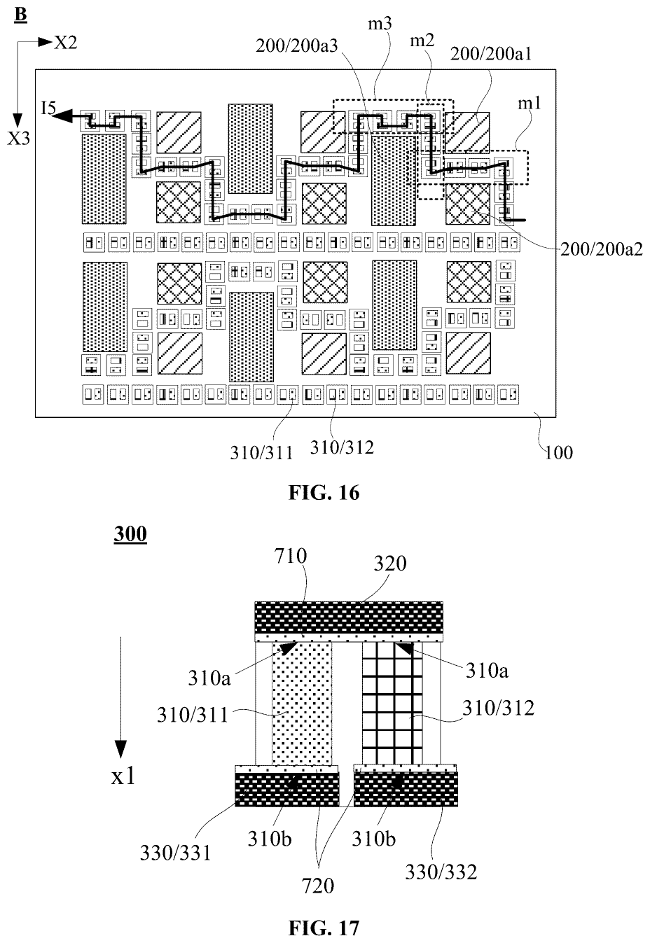

FIG. 16 is a third enlarged view of region B in FIG. 1. Referring to FIG. 16, multiple thermoelectric conversion units 300 sequentially connected in series in the third series sub-branch m3 are arranged in a serpentine shape.

Further, the arrangement manner of the multiple thermoelectric conversion units 300 in the display panel 10 varies, for which reference may be made to FIG. 15 or FIG. 16. Further, referring to FIG. 16, the third series sub-branch m3 includes multiple thermoelectric conversion units 300 connected in series, and the multiple thermoelectric conversion units 300 are arranged in a serpentine shape. The serpentine arrangement may be understood as follows: in the thermoelectric conversion units 300 at a corresponding location, the first thermocouple arm 311 and the second thermocouple arm 312 are arranged in the third direction X3, and for two adjacent thermoelectric conversion units 300 arranged in the second direction X2, the direction in which the first thermocouple arm 311 points to the second thermocouple arm 312 is opposite. In other words, if the direction in which the first thermocouple arm 311 points to the second thermocouple arm 312 in a thermoelectric conversion unit 300 is the same as the third direction X3, the thermoelectric conversion unit 300 is considered “positive”; if the direction in which the first thermocouple arm 311 points to the second thermocouple arm 312 in a thermoelectric conversion unit 300 is opposite to the third direction X3, the thermoelectric conversion unit 300 is considered “negative”. Therefore, in the third series sub-branch m3, the multiple thermoelectric conversion units 300 are arranged in the second direction X2 in an alternating pattern of “positive, negative, positive, negative, . . . ”. Further, referring to FIG. 15, the current flow direction in the third series sub-branch m3 is also a serpentine path. Specifically, the arrangement of the multiple thermoelectric conversion units 300 may be adjusted, demonstrating the diversity of the arrangement manner of the thermoelectric conversion units 300.

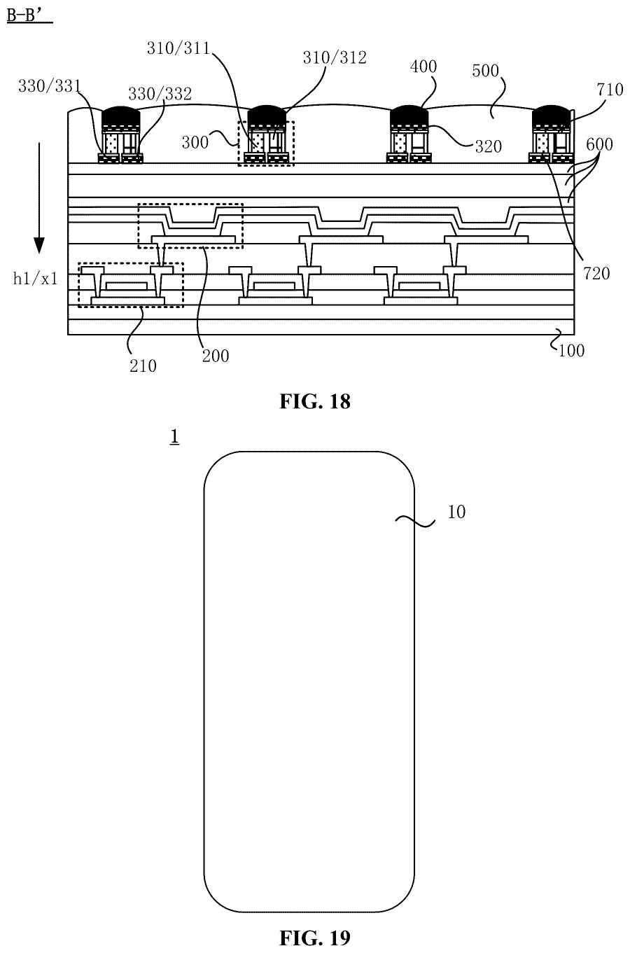

FIG. 17 is an enlarged view of a second type of thermoelectric conversion unit according to an embodiment of the present disclosure, and FIG. 18 is a fourth sectional view of FIG. 2 taken along a section line B-B′. Referring to FIGS. 17 and 18, a first blocking layer 710 is disposed between the first thermocouple arm 311 and the hot-end electrode 320 and between the second thermocouple arm 312 and the hot-end electrode 320, and the diffusion activation energy of the material of the first blocking layer 710 is greater than the diffusion activation energy of the material of the hot-end electrode 320. A second blocking layer 720 is disposed between the first thermocouple arm 311 and the cold-end electrode 310 and between the second thermocouple arm 312 and the cold-end electrode 310, and the diffusion activation energy of the material of the second blocking layer 720 is greater than the diffusion activation energy of the material of the cold-end electrode 310.

Further, referring to FIGS. 17 and 18, a first blocking layer 710 and a second blocking layer 720 are further provided in the thermoelectric conversion unit 300. The first blocking layer 710 and the second blocking layer 720 are more dense to protect the thermoelectric conversion unit 300, thereby ensuring the working stability of the thermoelectric conversion unit 300.

Specifically, a first blocking layer 710 is disposed between the first thermocouple arm 311 and the hot-end electrode 320 and between the second thermocouple arm 312 and the hot-end electrode 320, and the diffusion activation energy of the material of the first blocking layer 710 is greater than the diffusion activation energy of the material of the hot-end electrode 320. Therefore, the first blocking layer 710 may prevent some substances in the hot-end electrode 320, such as copper ions, from entering the first thermocouple arm 311 or the second thermocouple arm 312, thereby ensuring the stability of the thermocouple arm 310 in the thermoelectric conversion unit 300. Further, a second blocking layer 720 is disposed between the first thermocouple arm 311 and the cold-end electrode 310 and between the second thermocouple arm 312 and the cold-end electrode 310, and the diffusion activation energy of the material of the second blocking layer 720 is greater than the diffusion activation energy of the material of the cold-end electrode 310. Therefore, the second blocking layer 720 disposed between the first thermocouple arm 311 and the cold-end electrode 310 may prevent some substances in the cold-end electrode 310, such as copper ions, from entering the first thermocouple arm 311, and the second blocking layer 720 disposed between the second thermocouple arm 312 and the cold-end electrode 310 may prevent some substances in the cold-end electrode 310, such as copper ions, from entering the second thermocouple arm 312, thereby ensuring the stability of the thermocouple arm 310 in the thermoelectric conversion unit 300.

Specifically, in the thermoelectric conversion unit 300, the primary functions of the first blocking layer 710 and the second blocking layer 720 are as follows: First, the first blocking layer 710 and the second blocking layer 720 may be understood as dense film structures, and since the hot-end electrode 320 and the cold-end electrode 310 are mostly highly conductive metals that are prone to generating conductive ions, the first blocking layer 710 and the second blocking layer 720 may effectively block the cross-sectional diffusion of these conductive ions, that is, the first blocking layer 710 and the second blocking layer 720 serve to suppress element diffusion. Second, the first blocking layer 710 and the second blocking layer 720 exhibit strong thermodynamic stability and are less likely to react with thermoelectric materials, that is, the first blocking layer 710 and the second blocking layer 720 function to prevent interfacial reactions. Further, the thermocouple arm 310 is in contact with the blocking layers to form an Ohmic contact, thereby effectively reducing the contact resistance of the thermocouple arm 310. Additionally, the first blocking layer 710 and the second blocking layer 720 generally possess good ductility and thus may alleviate thermal stress in the thermoelectric conversion unit 300, thereby ensuring the structural stability of the thermoelectric conversion unit 300.

In one or more embodiments, referring to FIGS. 17 and 18, the material of the hot-end electrode 320 and the material of the cold-end electrode 310 include any one of copper, aluminum, gold, silver, indium, porous nickel, molybdenum, copper-molybdenum alloy or copper-tungsten alloy. The material of the first blocking layer 710 and the material of the second blocking layer 720 include any one of gold, silver, tantalum, copper, titanium, titanium nitride, titanium tungsten alloy, nickel or molybdenum.

The hot-end electrode 320 and the cold-end electrode 310 in the thermoelectric conversion unit 300 may be prepared from any one of copper, aluminum, gold, silver, indium, porous nickel, molybdenum, copper-molybdenum alloy or copper-tungsten alloy, and the first blocking layer 710 and the second blocking layer 720 in the thermoelectric conversion unit 300 may be prepared from any one of gold, silver, tantalum, copper, titanium, titanium nitride, titanium tungsten alloy, nickel or molybdenum, provided that the diffusion activation energies of the materials of the first blocking layer 710 and the second blocking layer 720 are larger than the diffusion activation energies of the materials of the hot-end electrode 320 and the cold-end electrode 310. Therefore, the material selection for the hot-end electrode 320, the cold-end electrode 310, the first blocking layer 710 and the second blocking layer 720 exhibits significant diversity.

In one or more embodiments, the first thermocouple arm 311 is made of any one of a (Bi, Sb)₂Te₃-based material, a PbTe-based material or a CoSb₃-based material, and is doped with any one of sodium, potassium or silver; and/or the second thermocouple arm 312 is made of any one of a (Bi, Sb)₂Te₃-based material, a PbTe-based material or a CoSb₃-based material, which is doped with any one of iodine, bromine or cuprous iodide.

The first thermocouple arm 311 in the thermoelectric conversion unit 300 may be prepared from any one of a (Bi, Sb)₂Te₃-based material, a PbTe-based material or a CoSb₃-based material, doped with any one of sodium, potassium or silver. The (Bi, Sb)₂Te₃-based material may be understood as a base material formed by the solid solution of Bi₂Te₃ and Sb₂Te₃, and the chemical formula of such a material may be expressed as (Bi₁₋ₓSbₓ)₂Te₃. Further, the second thermocouple arm 312 may also be prepared from any one of a (Bi, Sb)₂Te₃-based material, a PbTe-based material or a CoSb₃-based material, doped with any one of sodium, potassium or silver. Therefore, the material selection for the first thermocouple arm 311 and the second thermocouple arm 312 exhibits significant diversity.

Further, the doping concentration Nₐ of a dopant in the first thermocouple arm 311 satisfies: 10¹⁹ cm⁻³≤Nₐ≤10²⁰ cm⁻³ and/or the doping concentration N_{d} of a dopant in the second thermocouple arm 312 satisfies: 10¹⁹ cm⁻³≤N_{d}≤10²⁰ cm⁻³.

Further, in the thermoelectric conversion unit 300, the doping concentration Nₐ of the dopant in the first thermocouple arm 311 satisfies: 10¹⁹ cm⁻³≤Nₐ≤10²⁰ cm⁻³. By selecting an appropriate base material and a dopant with a suitable doping concentration for the first thermocouple arm 311, the working efficiency of the first thermocouple arm 311 may be improved, that is, an electromotive force is generated when a temperature difference exists. Further, in the thermoelectric conversion unit 300, the doping concentration N_{d} of the dopant in the second thermocouple arm 312 satisfies: 10¹⁹ cm⁻³≤N_{d}≤10²⁰ cm⁻³. By selecting an appropriate base material and a dopant with a suitable doping concentration for the second thermocouple arm 312, the working efficiency of the second thermocouple arm 312 may be improved, that is, an electromotive force is generated when a temperature difference exists. Therefore, the working stability and reliability of the thermoelectric conversion unit 300 are ensured.

In one or more embodiments, the height H of the first thermocouple arm 311 and the height H of the second thermocouple arm 312 satisfy: 5 μm≤H≤10 μm and/or the maximum cross-sectional width W of the first thermocouple arm 311 and the maximum cross-sectional width W of the second thermocouple arm 312 satisfy: 10 μm≤W≤15 μm.

Further, referring to FIGS. 2 to 18, the height H of the first thermocouple arm 311 and the height H of the second thermocouple arm 312 satisfy: 5 μm≤H≤10 μm, and H may be any number of 5 μm, 7 μm, 7.5 μm, 9 μm or 10 μm. The specific heights of the first thermocouple arm 311 and the second thermocouple arm 312 are not limited in the embodiments of the present disclosure. Further, the maximum cross-sectional width W of the first thermocouple arm 311 and the maximum cross-sectional width W of the second thermocouple arm 312 satisfy: 10 μm≤W≤15 μm, and W may be any number of 10 μm, 12 μm, 12.5 μm, 12.75 μm, 14 μm or 15 μm. The specific cross-sectional areas of the first thermocouple arm 311 and the second thermocouple arm 312 are not limited in the embodiments of the present disclosure.

Based on the same inventive concept, embodiments of the present disclosure further provide a display device. FIG. 19 is a structure diagram of a display device according to an embodiment of the present disclosure. As shown in FIG. 19, the display device 1 includes the display panel 10 of any embodiment of the present disclosure. Therefore, the display device 1 provided by the embodiments of the present disclosure has the corresponding beneficial effects of the preceding embodiments, and the details are not repeated here. The display device 1 may be an electronic device such as a mobile phone, a computer, a smart wearable device and an in-vehicle display device.

It is to be noted that the preceding are preferred embodiments of the present disclosure and technical principles used therein. It is to be understood by those skilled in the art that the present disclosure is not limited to the specific embodiments described herein. Those skilled in the art can make various apparent modifications, adaptations, combinations, and substitutions without departing from the scope of the present disclosure. Therefore, although the present disclosure has been described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A display panel, comprising:
a base substrate; and
a plurality of light-emitting units and a plurality of thermoelectric conversion units, located on a side of the base substrate in a thickness direction, wherein an orthographic projection of a thermoelectric conversion unit of the plurality of thermoelectric conversion units on the base substrate does not overlap with an orthographic projection of a light-emitting unit of the plurality of light-emitting units on the base substrate;
wherein the thermoelectric conversion unit comprises a thermocouple arm, and when a temperature difference exists between two ends of the thermocouple arm facing away from each other, carriers diffuse from a hot end to a cold end to form an electromotive force.

2. The display panel according to claim 1, wherein the thermocouple arm comprises a first thermocouple arm and a second thermocouple arm, the first thermocouple arm is made of a P-type semiconductor material, and the second thermocouple arm is made of an N-type semiconductor material; and the first thermocouple arm and the second thermocouple arm extend in parallel in a first direction and are insulated from each other, wherein the first direction and the base substrate intersect;
the thermoelectric conversion unit further comprises a hot-end electrode and a cold-end electrode, and the cold-end electrode comprises a first cold-end sub-electrode and a second cold-end sub-electrode;
the hot-end electrode is located on a side of the first thermocouple arm and the second thermocouple arm facing away from the base substrate, and the hot-end electrode is electrically connected to the first thermocouple arm and the second thermocouple arm, respectively; and
the cold-end electrode is located on a side of the first thermocouple arm and the second thermocouple arm facing the base substrate, the first cold-end sub-electrode is electrically connected to the first thermocouple arm, the second cold-end sub-electrode is electrically connected to the second thermocouple arm, and the first cold-end sub-electrode is insulated from the second cold-end sub-electrode.

3. The display panel according to claim 2, further comprising a plurality of black light-absorbing portions, wherein the plurality of black light-absorbing portions are located at ends of the plurality of thermoelectric conversion units facing away from the base substrate in one-to-one correspondence; and the orthographic projection of the thermoelectric conversion unit on the base substrate is located in an orthographic projection of a black light-absorbing portion of the plurality of black light-absorbing portions on the base substrate, and the orthographic projection of the black light-absorbing portion on the base substrate does not overlap with the orthographic projection of the light-emitting unit on the base substrate.

4. The display panel according to claim 3, further comprising a plurality of color resists, wherein the plurality of color resists are located at light emission sides of the plurality of light-emitting units in one-to-one correspondence, and an emitted color of each of the plurality of color resists is the same as an emitter color of a respective one of the plurality of light-emitting units;
the orthographic projection of the light-emitting unit on the base substrate is located in an orthographic projection of a color resist of the plurality of color resists on the base substrate; and
an orthographic projection of the color resist on a plane perpendicular to the base substrate at least partially overlaps with an orthographic projection of the black light-absorbing portion on the plane perpendicular to the base substrate.

5. The display panel according to claim 3, wherein the black light-absorbing portion is made of at least one of carbon black, lactam black, perylene black or aniline black.

6. The display panel according to claim 2, further comprising a touch layer, wherein the touch layer comprises a touch electrode, and an orthographic projection of the touch electrode on the base substrate does not overlap with the orthographic projection of the light-emitting unit on the base substrate and does not overlap with the orthographic projection of the thermoelectric conversion unit on the base substrate.

7. The display panel according to claim 6, wherein in a direction perpendicular to the base substrate, the touch layer is located between a film layer where the plurality of thermoelectric conversion units are located and a film layer where the plurality of light-emitting units are located.

8. The display panel according to claim 7, wherein thermoelectric conversion units among the plurality of thermoelectric conversion units are sequentially connected in series to form a series branch, and in the series branch, two adjacent thermoelectric conversion units comprise a first sub-thermoelectric conversion unit and a second sub-thermoelectric conversion unit; and
a first cold-end sub-electrode of the first sub-thermoelectric conversion unit is electrically connected to a second cold-end sub-electrode of the second sub-thermoelectric conversion unit.

9. The display panel according to claim 6, wherein the plurality of thermoelectric conversion units comprise a plurality of first thermoelectric conversion units and a plurality of second thermoelectric conversion units, wherein the plurality of first thermoelectric conversion units are located in a same film layer, and the plurality of second thermoelectric conversion units are located in a same film layer; and
in a direction perpendicular to the base substrate and facing away from the base substrate, the film layer where the plurality of light-emitting units are located, the film layer where the plurality of second thermoelectric conversion units are located, the touch layer and the film layer where the plurality of first thermoelectric conversion units are located are sequentially arranged.

10. The display panel according to claim 9, wherein
first thermoelectric conversion units among the plurality of first thermoelectric conversion units are sequentially connected in series to form a first series branch, and in the first series branch, two adjacent first thermoelectric conversion units comprise a first sub-thermoelectric conversion unit and a second sub-thermoelectric conversion unit;
a first cold-end sub-electrode of the first sub-thermoelectric conversion unit is electrically connected to a second cold-end sub-electrode of the second sub-thermoelectric conversion unit;
second thermoelectric conversion units among the plurality of second thermoelectric conversion units are sequentially connected in series to form a second series branch, and in the second series branch, two adjacent second thermoelectric conversion units comprise a third sub-thermoelectric conversion unit and a fourth sub-thermoelectric conversion unit; and
a first cold-end sub-electrode of the third sub-thermoelectric conversion unit is electrically connected to a second cold-end sub-electrode of the fourth sub-thermoelectric conversion unit.

11. The display panel according to claim 9, wherein first thermoelectric conversion units among the plurality of first thermoelectric conversion units and second thermoelectric conversion units among the plurality of second thermoelectric conversion units are sequentially connected in series to form a series branch; and in the series branch, two adjacent first thermoelectric conversion units comprise a first sub-thermoelectric conversion unit and a second sub-thermoelectric conversion unit, two adjacent second thermoelectric conversion units comprise a third sub-thermoelectric conversion unit and a fourth sub-thermoelectric conversion unit, and the second sub-thermoelectric conversion unit is adjacent to the third sub-thermoelectric conversion unit; and
a first cold-end sub-electrode of the first sub-thermoelectric conversion unit is electrically connected to a second cold-end sub-electrode of the second sub-thermoelectric conversion unit, a first cold-end sub-electrode of the second sub-thermoelectric conversion unit is electrically connected to a second cold-end sub-electrode of the third sub-thermoelectric conversion unit, and a first cold-end sub-electrode of the third sub-thermoelectric conversion unit is electrically connected to a second cold-end sub-electrode of the fourth sub-thermoelectric conversion unit.

12. The display panel according to claim 9, further comprising a plurality of first black light-absorbing portions and a plurality of second black light-absorbing portions;
the plurality of first black light-absorbing portions are located at terminals of the plurality of first thermoelectric conversion units facing away from the base substrate in one-to-one correspondence; and an orthographic projection of a first thermoelectric conversion unit of the plurality of first thermoelectric conversion units on the base substrate is located in an orthographic projection of a first black light-absorbing portion of the plurality of first black light-absorbing portions on the base substrate, and the orthographic projection of the first black light-absorbing portion on the base substrate does not overlap with the orthographic projection of the light-emitting unit on the base substrate; and
the plurality of second black light-absorbing portions are located at terminals of the plurality of second thermoelectric conversion units facing away from the base substrate in one-to-one correspondence; and an orthographic projection of a second thermoelectric conversion unit of the plurality of second thermoelectric conversion units on the base substrate is located in an orthographic projection of a second black light-absorbing portion of the plurality of second black light-absorbing portions on the base substrate, and the orthographic projection of the second black light-absorbing portion on the base substrate does not overlap with the orthographic projection of the light-emitting unit on the base substrate.

13. The display panel according to claim 12, wherein an area of the orthographic projection of the first black light-absorbing portion on the base substrate is smaller than an area of the orthographic projection of the second black light-absorbing portion on the base substrate; and
an orthographic projection of at least one first black light-absorbing portion of the plurality of first black light-absorbing portions on the base substrate and the orthographic projection of the touch electrode on the base substrate are located in an orthographic projection of a same second black light-absorbing portion of the plurality of second black light-absorbing portions on the base substrate.

14. The display panel according to claim 2, wherein at least two light-emitting units of different emitted colors of the plurality of light-emitting units form one pixel unit, a plurality of pixel units sequentially arranged in a second direction form a pixel unit row, and a plurality of pixel unit rows are sequentially arranged in a third direction; wherein the second direction and the third direction are parallel to the base substrate and intersect with each other;
in an orthographic projection of the base substrate, at least part of the plurality of thermoelectric conversion units are located between adjacent pixel unit rows of the plurality of pixel unit rows and sequentially connected in series to form a series branch, and series branches between different adjacent pixel unit rows are connected in parallel; and
in the series branch, two adjacent thermoelectric conversion units comprise a first sub-thermoelectric conversion unit and a second sub-thermoelectric conversion unit; and a first cold-end sub-electrode of the first sub-thermoelectric conversion unit is electrically connected to a second cold-end sub-electrode of the second sub-thermoelectric conversion unit.

15. The display panel according to claim 2, wherein at least two light-emitting units of different emitted colors of the plurality of light-emitting units form one pixel unit, a plurality of pixel units sequentially arranged in a second direction form a pixel unit row, and a plurality of pixel unit rows are sequentially arranged in a third direction; wherein the second direction and the third direction are parallel to the base substrate and intersect with each other;
in an orthographic projection of the base substrate, at least part of the plurality of thermoelectric conversion units is located between adjacent light-emitting units of the at least two light-emitting units in the pixel unit and sequentially connected in series to form a series branch, and series branches in different pixel unit rows are connected in parallel; and
in the series branch, two adjacent thermoelectric conversion units comprise a first sub-thermoelectric conversion unit and a second sub-thermoelectric conversion unit; and a first cold-end sub-electrode of the first sub-thermoelectric conversion unit is electrically connected to a second cold-end sub-electrode of the second sub-thermoelectric conversion unit.

16. The display panel according to claim 15, wherein the pixel unit comprises a first light-emitting unit, a second light-emitting unit and a third light-emitting unit, and the first light-emitting unit, the second light-emitting unit and the third light-emitting unit have different emitted colors;
the first light-emitting unit and the second light-emitting unit are arranged in the third direction, and a combination of the first light-emitting unit and the second light-emitting unit and the third light-emitting unit are alternately arranged in the second direction;
the series branch comprises a plurality of first series sub-branches, a plurality of second series sub-branches and a plurality of third series sub-branches;
a first series sub-branch of the plurality of first series sub-branches is located between the first light-emitting unit and the second light-emitting unit, and thermoelectric conversion units in the first series sub-branch are sequentially arranged in the second direction;
a second series sub-branch of the plurality of second series sub-branches is located between the combination of the first light-emitting unit and the second light-emitting unit and the third light-emitting unit, and thermoelectric conversion units in the second series sub-branch are sequentially arranged in the third direction; and
a third series sub-branch of the plurality of third series sub-branches and the third light-emitting unit are arranged in the third direction, and two adjacent third light-emitting units and corresponding third series sub-branches are arranged in an alternating positional orientation along the third direction,
wherein a plurality of thermoelectric conversion units sequentially connected in series in the third series sub-branch are arranged in a serpentine shape.

17. The display panel according to claim 2, wherein a first blocking layer is disposed between the first thermocouple arm and the hot-end electrode and between the second thermocouple arm and the hot-end electrode, and a diffusion activation energy of a material of the first blocking layer is greater than a diffusion activation energy of a material of the hot-end electrode; and
a second blocking layer is respectively disposed between the first thermocouple arm and the cold-end electrode and between the second thermocouple arm and the cold-end electrode, and a diffusion activation energy of a material of the second blocking layer is greater than a diffusion activation energy of a material of the cold-end electrode,
wherein the material of the hot-end electrode and the material of the cold-end electrode each comprises any one of copper, aluminum, gold, silver, indium, porous nickel, molybdenum, copper-molybdenum alloy or copper-tungsten alloy; and
the material of the first blocking layer and the material of the second blocking layer each comprises any one of gold, silver, tantalum, copper, titanium, titanium nitride, titanium tungsten alloy, nickel or molybdenum.

18. The display panel according to claim 2, wherein at least one of the following conditions is satisfied: the first thermocouple arm is made of any one of a (Bi, Sb)₂Te₃-based material, a PbTe-based material or a CoSb₃-based material, and is doped with any one of sodium, potassium or silver; or the second thermocouple arm is made of any one of a (Bi, Sb)₂Te₃-based material, a PbTe-based material or a CoSb₃-based material, which is doped with any one of iodine, bromine or cuprous iodide,
wherein at least one of the following conditions is satisfied: a doping concentration Nₐ of a dopant in the first thermocouple arm satisfies: 10¹⁹ cm⁻³≤Nₐ≤10²⁰ cm⁻³ or a doping concentration N_{d} of a dopant in the second thermocouple arm satisfies: 10¹⁹ cm⁻³≤N_{d}≤10²⁰ cm⁻³.

19. The display panel according to claim 2, wherein at least one of the following conditions is satisfied: a height H of the first thermocouple arm and a height H of the second thermocouple arm satisfy: 5 μm≤H≤10 μm or a maximum cross-sectional width W of the first thermocouple arm and a maximum cross-sectional width W of the second thermocouple arm satisfy: 10 μm≤W≤15 μm.

20. A display device, comprising the display panel according to claim 1.
